(19) United States
(12) Patent Application Publication
(10) Pub. No.: US 2026/0096156 A1
(43) Pub. Date: Apr. 2, 2026

(54) SEMICONDUCTOR DEVICE AND MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: TOMOTAKA ARIGA, Nisshin-shi (JP); HIDEMOTO TOMITA, Nisshin-shi (JP)

(21) Appl. No.: 19/270,923

(22) Filed: Jul. 16, 2025

(30) Foreign Application Priority Data
Sep. 27, 2024 (JP) 2024-169044

(51) Int. Cl. H10D 62/00; H10D 30/66; H10D 62/10; H10D 62/832

(52) U.S. Cl. CPC H10D 62/054; H10D 30/668; H10D 62/111; H10D 62/8325

(57) ABSTRACT

A manufacturing method of a semiconductor device includes patterning an ion implantation mask above a second conductivity type semiconductor layer, and forming first conductivity type columns and second conductivity type columns within the second conductivity type semiconductor layer by implanting first conductivity type impurity ions into the second conductivity type semiconductor layer through openings in the ion implantation mask. The patterning the ion implantation mask includes forming a mask forming layer above the second conductivity type semiconductor layer, forming grooves extending from an upper surface of the mask forming layer toward the second conductivity type semiconductor layer, embedding a shielding portion containing metal into the grooves, and removing the mask forming layer located between the shielding portion to form the openings.

### CROSS REFERENCE TO RELATED APPLICATION

The present application claims the benefit of priority from Japanese Patent Application No. 2024-169044 filed on Sep. 27, 2024. The entire disclosure of the above application is incorporated herein by reference.

### TECHNICAL FIELD

The present disclosure relates to a semiconductor device and a manufacturing method of a semiconductor device.

### BACKGROUND

Semiconductor devices having a superjunction structure in which p-type columns and n-type columns are alternately and repeatedly arranged along at least one direction have been proposed. The semiconductor devices having the superjunction structure can achieve both low on-resistance and high breakdown voltage characteristics.

### SUMMARY

According to an aspect of the present disclosure, a manufacturing method of a semiconductor device having a superjunction structure in which first conductivity type columns and second conductivity type columns are alternately and repeatedly arranged along at least one direction is provided. The manufacturing method includes patterning an ion implantation mask above a second conductivity type semiconductor layer and forming the first conductivity type columns and the second conductivity type columns within the second conductivity type semiconductor layer by implanting first conductivity type impurity ions into the second conductivity type semiconductor layer through openings in the ion implantation mask. The patterning the ion implantation mask may include forming a mask forming layer above the second conductivity type semiconductor layer, forming grooves extending from an upper surface of the mask forming layer toward the second conductivity type semiconductor layer, embedding a shielding portion containing metal into the grooves, and removing the mask forming layer located between the shielding portion to form the openings.

### BRIEF DESCRIPTION OF DRAWINGS

Objects, features and advantages of the present disclosure will become apparent from the following detailed description made with reference to the accompanying drawings. In the drawings:

FIG. 1 is a diagram schematically showing a partial cross-sectional view of a semiconductor device according to an embodiment of the present disclosure;

FIG. 2 is a diagram schematically showing a partial cross-sectional view in a process in a first manufacturing method of the semiconductor device;

FIG. 3 is a diagram schematically showing a partial cross-sectional view in a process in the first manufacturing method of the semiconductor device;

FIG. 4 is a diagram schematically showing a partial cross-sectional view in a process in the first manufacturing method of the semiconductor device;

FIG. 5 is a diagram schematically showing a partial cross-sectional view in a process in the first manufacturing method of the semiconductor device;

FIG. 6 is a diagram schematically showing a partial cross-sectional view in a process in the first manufacturing method of the semiconductor device;

FIG. 7 is a diagram schematically showing a partial cross-sectional view in a process in the first manufacturing method of the semiconductor device;

FIG. 8 is a diagram schematically showing a partial cross-sectional view in a process in the first manufacturing method of the semiconductor device;

FIG. 9 is a diagram schematically showing a partial cross-sectional view in a process in the first manufacturing method of the semiconductor device;

FIG. 10 is a diagram schematically showing a partial cross-sectional view in a process in the first manufacturing method of the semiconductor device;

FIG. 11 is a diagram schematically showing a partial cross-sectional view in a process in the first manufacturing method of the semiconductor device;

FIG. 12 is a diagram schematically showing a partial cross-sectional view in a process in a second manufacturing method of the semiconductor device;

FIG. 13 is a diagram schematically showing a partial cross-sectional view in a process in the second manufacturing method of the semiconductor device;

FIG. 14 is a diagram schematically showing a partial cross-sectional view in a process in the second manufacturing method of the semiconductor device;

FIG. 15 is a diagram schematically showing a partial cross-sectional view in a process in the second manufacturing method of the semiconductor device;

FIG. 16 is a diagram schematically showing a partial cross-sectional view in a process in the second manufacturing method of the semiconductor device;

FIG. 17 is a diagram schematically showing a partial cross-sectional view in a process in the second manufacturing method of the semiconductor device;

FIG. 18 is a diagram schematically showing a partial cross-sectional view in a process in the second manufacturing method of the semiconductor device;

FIG. 19 is a diagram schematically showing a partial cross-sectional view in a process in the second manufacturing method of the semiconductor device; and

FIG. 20 is a diagram schematically showing a partial cross-sectional view in a process in the second manufacturing method of the semiconductor device.

### DETAILED DESCRIPTION

In order to improve characteristics of low on-resistance and high breakdown voltage in semiconductor devices having a superjunction structure, it is desirable to increase aspect ratios of both p-type columns and n-type columns. The superjunction structure may be formed by ion-implanting an impurity of one conductivity type (for example, a p-type impurity) into a semiconductor layer of the opposite conductivity type (for example, an n-type semiconductor layer). As a mask for ion implantation, a photoresist with openings corresponding to ion implantation regions may be used. In order to both shield a conductivity type impurity to be ion-implanted and form high aspect ratio columns, it is necessary to increase a thickness of the photoresist and narrow a pitch of the openings formed in the photoresist. Therefore, in the photoresist used to form high aspect ratio columns, the aspect ratio of the openings formed also becomes high. According to investigations by the present inventors, it has been found that there is a concern that the photoresist may collapse when the aspect ratio of the openings formed in the photoresist increases.

According to a first aspect of the present disclosure, a manufacturing method of a semiconductor device having a superjunction structure in which first conductivity type columns and second conductivity type columns are alternately and repeatedly arranged along at least one direction is provided. The manufacturing method includes patterning an ion implantation mask above a second conductivity type semiconductor layer, and after the patterning the ion implantation mask, forming the first conductivity type columns and the second conductivity type columns by implanting first conductivity type impurity ions into the second conductivity type semiconductor layer through openings in the ion implantation mask. The patterning the ion implantation mask includes forming a mask forming layer above the second conductivity type semiconductor layer, forming grooves extending from an upper surface of the mask forming layer toward the second conductivity type semiconductor layer, embedding a shielding portion containing metal into the grooves, and removing the mask forming layer between the shielding portion to form the openings. The ion implantation mask used in the above manufacturing method includes the shielding portion containing metal. The shielding portion containing metal have high shielding properties against the first conductivity type impurity. Therefore, a film thickness of the ion implantation mask can be reduced. As a result, an aspect ratio of the openings formed in the ion implantation mask is reduced, thereby suppressing inclining of the ion implantation mask. Furthermore, the openings of the ion implantation mask are formed by removing portions of the mask forming layer that are located between the shielding portion embedded in the mask forming layer. Therefore, the openings of the ion implantation mask are not formed by directly etching the shielding portion. In contrast, in a case where openings are formed by directly etching a shielding portion containing metal, since etching proceeds along grain boundaries of the shielding portion, a maximum surface roughness of sidewalls of the openings may increase. In the above manufacturing method according to the first aspect, since the shielding portion is not directly etched, the maximum surface roughness of the openings of the ion implantation mask is reduced. As a result, a maximum surface roughness at interfaces between the first conductivity type columns and the second conductivity type columns formed within the second conductivity type semiconductor layer is also reduced. The semiconductor device manufactured by the above method can suppress charge imbalance in the superjunction structure and exhibit high breakdown voltage characteristics.

According to a second aspect of the present disclosure, a semiconductor device includes a superjunction structure in which first conductivity type columns and second conductivity type columns are alternately and repeatedly arranged in at least one direction as a repetition direction. Each of the first conductivity type columns and the second conductivity type columns is made of silicon carbide. A pitch of the first conductivity type columns and the second conductivity type columns in the repetition direction is 0.4 nm or less. A maximum surface roughness at interfaces between the first conductivity type columns and the second conductivity type columns is less than 30 nm.

Hereinafter, a semiconductor device according to an embodiment of the present disclosure will be described. For the purpose of clarity of drawings, when components are repeatedly arranged, only one of the components may be denoted by a reference numeral.

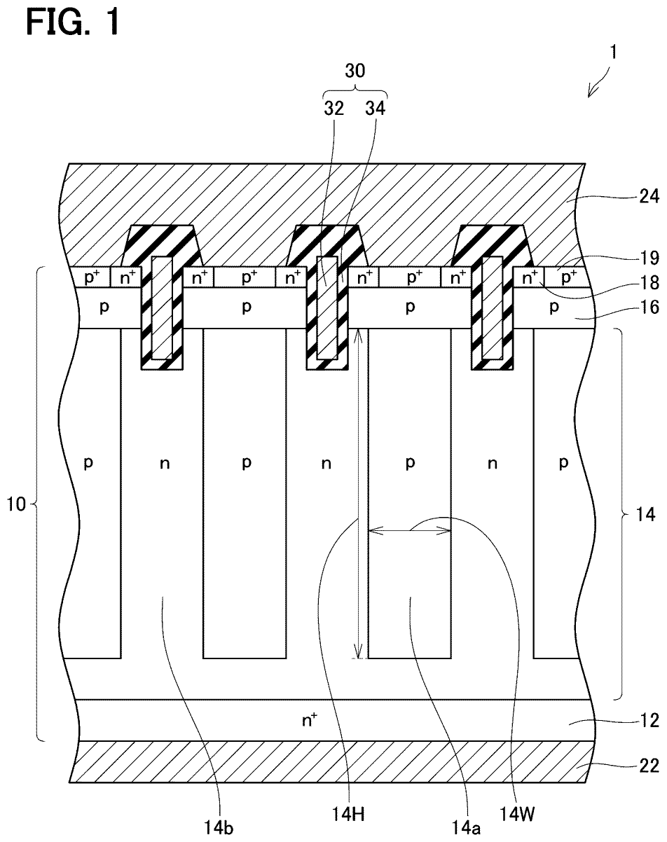

FIG. 1 is a diagram schematically showing a partial cross-sectional view of a semiconductor device 1. The semiconductor device 1 is a type of power semiconductor device called a metal oxide semiconductor field effect transistor (MOSFET), and includes a semiconductor layer 10, a drain electrode 22 covering a lower surface of the semiconductor layer 10, a source electrode 24 covering an upper surface of the semiconductor layer 10, and a plurality of trench gates 30 provided in an upper layer portion of the semiconductor layer 10.

The semiconductor layer 10 is made of a wide bandgap semiconductor. The semiconductor layer 10 is not particularly limited, and may be, for example, a 4H silicon carbide layer. The semiconductor layer 10 may be, instead of a silicon carbide layer, for example, a nitride semiconductor layer, a gallium oxide layer, a diamond layer, or the like. The semiconductor layer 10 includes a drain region 12 of n⁺-type, a drift region 14, a body region 16 of p-type, source regions 18 of n⁺-type, and body contact regions 19 of p⁺-type.

The drain region 12 is disposed in a lower portion of the semiconductor layer 10 and is provided at a position exposed on the lower surface of the semiconductor layer 10. The drain region 12 is in ohmic contact with the drain electrode 22 that covers the lower surface of the semiconductor layer 10. As will be described in a manufacturing method below, the drain region 12 is composed of a silicon carbide substrate of n⁺-type and an epitaxial layer of n⁺-type grown on an upper surface of the silicon carbide substrate.

The drift region 14 is disposed between the drain region 12 and the body region 16, and includes a plurality of p-type columns 14a and a plurality of n-type columns 14b. The p-type columns 14a are an example of first conductivity type columns, and the n-type columns 14b are an example of second conductivity type columns. The p-type columns 14a and n-type columns 14b are arranged so as to alternate with each other in at least one direction in a cross-section of the semiconductor layer 10, so as to form a superjunction structure. The plurality of p-type columns 14a and the plurality of n-type columns 14b are not particularly limited in their arrangement when viewed from a direction perpendicular to the upper surface of the semiconductor layer 10 (hereinafter referred to as “in plan view”), and, for example, may be arranged in a stripe pattern.

The p-type columns 14a have a height 14H measured from a lower surface to an upper surface, which is an interface with the body region 16, along a thickness direction of the semiconductor layer 10. The p-type columns 14a have a width 14W measured between side surfaces, which are interfaces with the n-type columns 14b, along a repetition direction of the superjunction structure. The height 14H of the p-type columns 14a is not particularly limited, and is, for example, 3.4 μm or more. The width 14W of the p-type columns 14a is not particularly limited, and is, for example, 0.4 μm or less. Accordingly, an aspect ratio of the p-type columns 14a is 8.5 or more. The width 14W of the p-type columns 14a is not particularly limited, and is, for example, 0.2 μm or more. The aspect ratio of the p-type columns 14a is not particularly limited, and is, for example, 17.8 or less. The height and width of the n-type columns 14b are the same as the p-type columns 14a. Thus, the pitch of the p-type columns 14a and the n-type columns 14b in the repetition direction is, for example, 0.4 μm or less. In addition, the pitch of the p-type columns 14a and the n-type columns 14b in the repetition direction is, for example, 0.2 μm or more. The superjunction structure with such dimensions results in a breakdown voltage of the semiconductor device 1 of 850 V or more, as calculated from the breakdown electric field of silicon carbide.

The body region 16 is disposed above the drift region 14 and is positioned in the upper layer portion of the semiconductor layer 10. The body region 16 is disposed between the n-type columns 14b of the drift region 14 and the source regions 18, and separates the n-type columns 14b from the source regions 18. A concentration of p-type impurities in the body region 16 is adjusted according to a desired gate threshold voltage.

The source regions 18 are disposed above the body region 16, are positioned in the upper layer portion of the semiconductor layer 10, and are formed at locations exposed on the upper surface of the semiconductor layer 10. The source regions 18 are in contact with side surfaces of the trench gates 30. The source regions 18 are in ohmic contact with the source electrode 24, which covers the upper surface of the semiconductor layer 10.

The body contact regions 19 are disposed above the body region 16, are positioned in the upper layer portion of the semiconductor layer 10, and are formed at locations exposed on the upper surface of the semiconductor layer 10. The body contact regions 19 are in ohmic contact with the source electrode 24, which covers the upper surface of the semiconductor layer 10.

The trench gates 30 are filled in trenches formed in the upper layer portion of the semiconductor layer 10, penetrate through the source regions 18 and the body region 16, and reach the n-type columns 14b of the drift region 14. In this example, the trench gates 30 extend, in plan view of the semiconductor layer 10, along a longitudinal direction of the p-type columns 14a and the n-type columns 14b, that is, a direction perpendicular to the repetition direction of the superjunction structure. In another example, the trench gates 30 may extend, in plan view of the semiconductor layer 10, along the repetition direction of the p-type columns 14a and the n-type columns 14b. Each of the trench gates 30 includes a gate electrode 32 and a gate insulating layer 34. The gate electrodes 32 are formed of polysilicon containing impurities, and face the semiconductor layer 10 via the gate insulating layers 34. In particular, the gate electrodes 32 face, via the gate insulating layers 34, portions of the body region 16 that separate the n-type columns 14b of the drift region 14 and the source regions 18. The gate insulating layer 34 is formed of silicon oxide and covers an inner wall of the trench.

Next, with reference to FIG. 1, the operation of the semiconductor device 1 will be described. When a potential of the gate electrodes 32 of the trench gates 30 is more positive than a potential of the source electrode 24 and is controlled to be higher than a threshold value in a state where a potential of the drain electrode 22 is more positive than the potential of the source electrode 24, the semiconductor device 1 is turned on. At this time, inversion layers are formed in the portions of the body region 16 that separate the n-type columns 14b of the drift region 14 and the source regions 18. Electrons supplied from the source regions 18 reach the n-type columns 14b of the drift region 14 via channels of the inversion layers. The electrons that have reached the n-type columns 14b flow into the drain region 12 via the n-type columns 14b. Since the n-type columns 14b have a high concentration of n-type impurities, the semiconductor device 1 can exhibit characteristics of low on-resistance.

When the potential of the gate electrodes 32 of the trench gates 30 is controlled to be the same as the potential of the source electrode 24, the channels of the inversion layers disappear, and the semiconductor device 1 is turned off. The p-type columns 14a and n-type columns 14b that constitute the superjunction structure are substantially fully depleted, and a wide region of the drift region 14 is depleted. In addition, since the drift region 14 has the superjunction structure, the electric field distribution in the drift region 14 is leveled in the depth direction. Therefore, the drift region 14 can withstand a large potential difference, so the semiconductor device 1 can have high breakdown voltage characteristics.

### (Manufacturing Method of Semiconductor Device)

Hereinafter, a first manufacturing method and a second manufacturing method of the semiconductor device 1 will be described with reference to the drawings. The following describes processes of forming the superjunction structure in the first manufacturing method of the semiconductor device 1. As detailed below, the superjunction structure is formed by vertically connecting p-type columns and n-type columns, each of which is formed in a lower epitaxial layer and an upper epitaxial layer, respectively. The other processes for manufacturing the semiconductor device 1 can utilize known manufacturing techniques as necessary.

### (First Manufacturing Method)

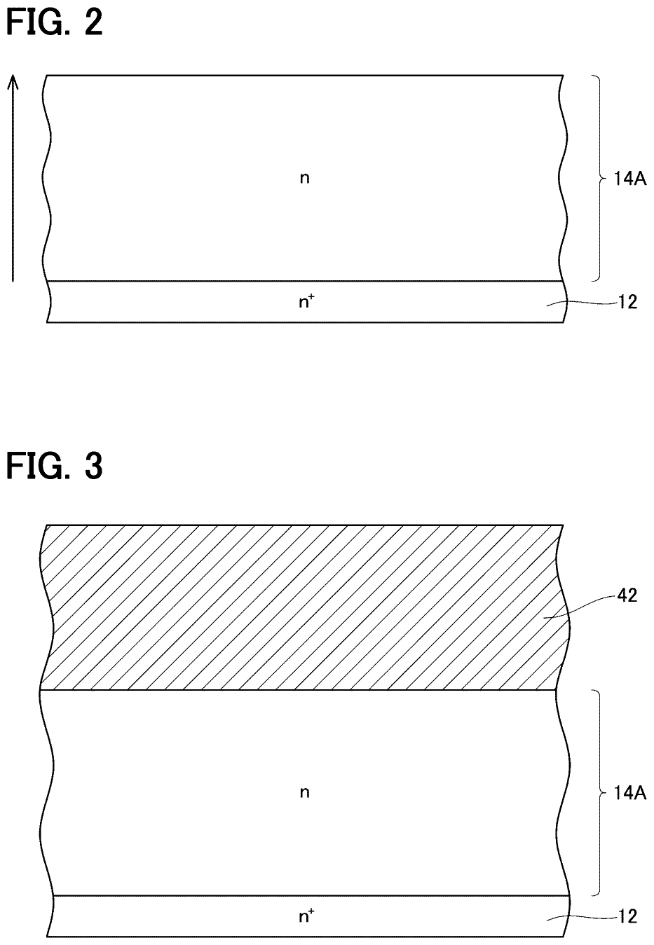

Hereinafter, the first manufacturing method of the semiconductor device 1 will be described with reference to FIGS. 2 to 11. First, as shown in FIG. 2, the drain region 12 is prepared. The drain region 12 is formed by growing an epitaxial layer of n⁺-type on a surface of a silicon carbide substrate of n⁺-type. Next, a lower epitaxial layer 14A of n-type is grown from a surface of the drain region 12 using epitaxial growth techniques. A thickness of the lower epitaxial layer 14A is not particularly limited, but may be, for example, 1.8 μm. It should be noted that the lower epitaxial layer 14A constitutes at least a part of the semiconductor layer 10, and may also be referred to as a semiconductor layer of n-type. The lower epitaxial layer 14A is an example of a second conductivity type semiconductor layer.

Next, as shown in FIG. 3, a mask forming layer 42 is deposited above the lower epitaxial layer 14A using vapor deposition techniques such as CVD, for example. The mask forming layer 42 is not particularly limited, and may be, for example, an oxide layer such as silicon oxide. A thickness of the mask forming layer 42 is not particularly limited, and may be, for example, 1.1 μm.

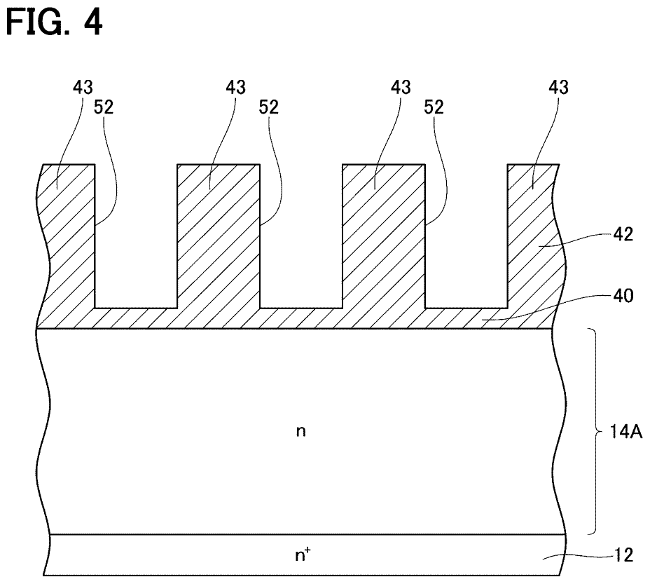

Next, as shown in FIG. 4, a plurality of grooves 52 are formed in the mask forming layer 42 using etching techniques such as a reactive ion etching (RIE) method or a wet etching method. Portions of the mask forming layer 42 that remain between the grooves 52 are referred to as mask forming walls 43. The grooves 52 extend from an upper surface of the mask forming layer 42 toward the lower epitaxial layer 14A. The grooves 52 do not penetrate through the mask forming layer 42. Therefore, the mask forming layer 42 is partially left above the lower epitaxial layer 14A. Portions of the mask forming layer 42 that have been left above the lower epitaxial layer 14A are referred to as the lift-off film 40. In another example, the grooves 52 may penetrate through the mask forming layer 42.

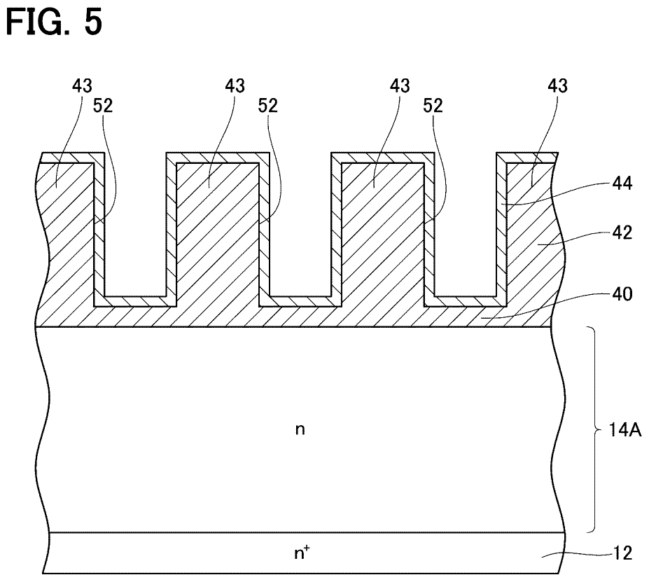

Next, as shown in FIG. 5, a sidewall film 44 is formed on inner walls of the grooves 52 using deposition techniques such as sputtering, for example. The sidewall film 44 is also formed on upper surfaces of the mask forming walls 43. The sidewall film 44 is a layer containing metal. The sidewall film 44 is not particularly limited, and may be, for example, a metal nitride layer. In this example, the sidewall film 44 is made of titanium nitride (TiN). In the sputtering method of forming the titanium nitride layer, for example, titanium (Ti) is used as a target, nitrogen gas (N₂) is used as a reactive gas, and argon gas (Ar) is used as an inert gas. In another example, the sidewall film 44 may be formed on the inner walls of the grooves 52 using atomic layer deposition, for example. As will be described in the second manufacturing method below, when the sidewall film 44 is formed by atomic layer deposition, the coverage of the sidewall film 44 is improved. Therefore, even if the pitch of the grooves 52 is narrow, the sidewall film 44 can be formed with good quality.

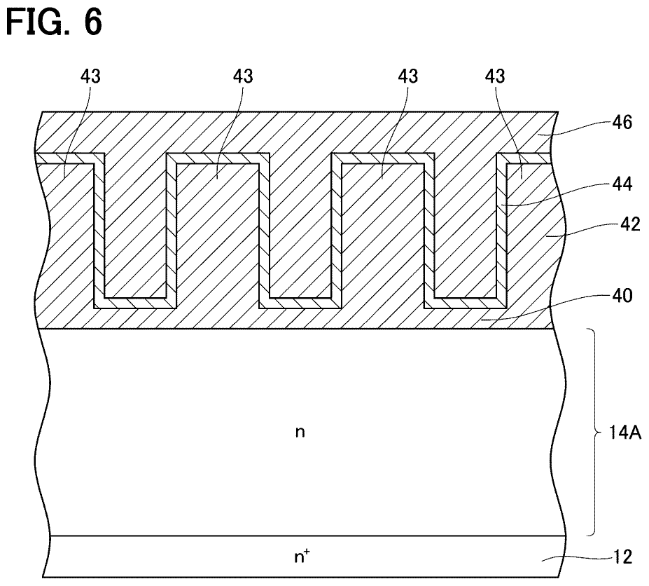

Next, as shown in FIG. 6, a shielding portion 46 is embedded in the grooves 52 using deposition techniques such as atomic layer deposition, for example. The shielding portion 46 is also formed above the upper surfaces of the mask forming walls 43 and completely fills the inside of the grooves 52. The shielding portion 46 is a film containing metal. The shielding portion 46 is not particularly limited and may be, for example, a single metal film. In this example, the shielding portion 46 is made of tungsten (W). In atomic layer deposition for forming the tungsten film, although not particularly limited, tungsten hexafluoride (WF₆), which is a metal precursor gas, and hydrogen (H₂), which is a reducing gas, may be used. The material of the shielding portion 46 may also be tungsten silicide (WSi₂).

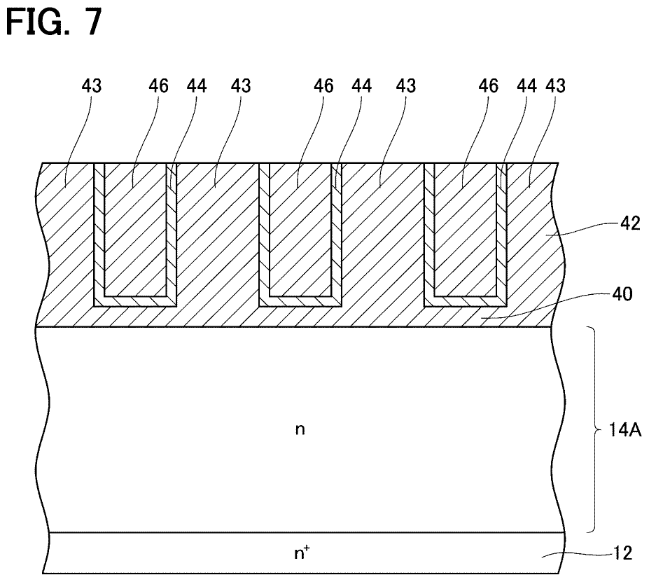

Next, as shown in FIG. 7, the shielding portion 46 that has been formed above the upper surfaces of the mask forming walls 43 is removed using planarization techniques such as chemical mechanical polishing (CMP), for example. In this planarization process, the sidewall film 44 that has been formed above the upper surfaces of the mask forming walls 43 is also removed, and the mask forming walls 43 are exposed.

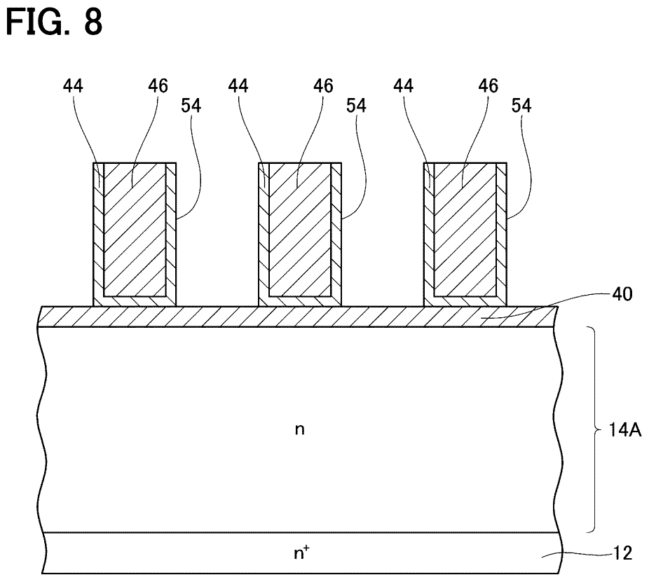

Next, as shown in FIG. 8, using etching techniques such as RIE or wet etching, the mask forming walls 43 present between the shielding portion 46 is removed to form openings 54, thereby forming an ion implantation mask. This ion implantation mask is an example of a first ion implantation mask. In this etching process, only the mask forming walls 43 are removed, and the lift-off film 40 that has been left above the lower epitaxial layer 14A is not removed. In another example, the openings 54 may penetrate through the lift-off film 40.

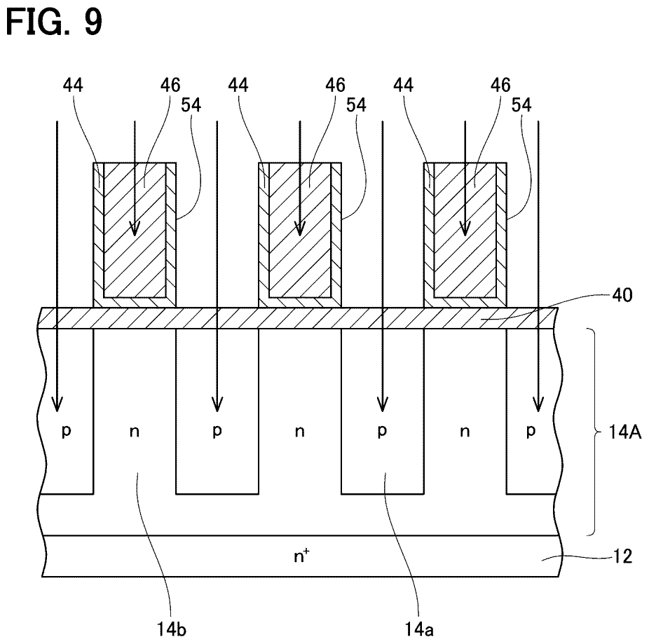

Next, as shown in FIG. 9, using ion implantation techniques, p-type impurity is ion-implanted into the lower epitaxial layer 14A through the openings 54 of the ion implantation mask. The p-type impurity is not particularly limited, and may be, for example, aluminum. Regions of the lower epitaxial layer 14A into which the p-type impurity has been introduced become the p-type columns 14a, and regions sandwiched between the p-type columns 14a become the n-type columns 14b. As a result, a structure in which the p-type columns 14a and the n-type columns 14b are alternately and repeatedly arranged along one direction is formed within the lower epitaxial layer 14A.

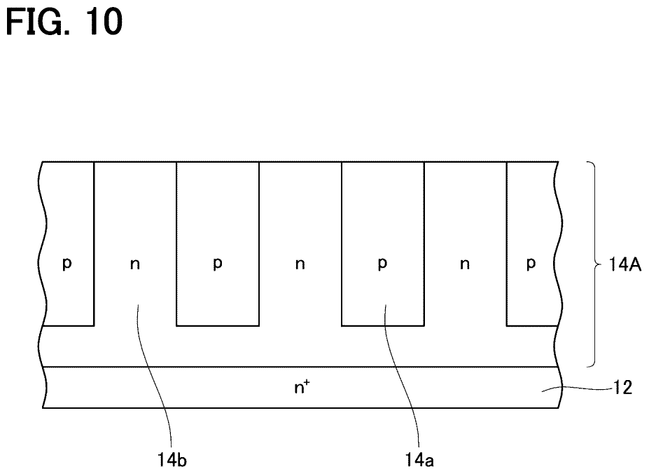

Next, as shown in FIG. 10, the lift-off film 40, the sidewall film 44, and the shielding portion 46 that have been formed above the lower epitaxial layer 14A are removed using a lift-off method. Specifically, by etching the lift-off film 40 using an etching solution (for example, hydrofluoric acid) that has a higher etching rate for the lift-off film 40 than for the sidewall film 44 and the shielding portion 46, the sidewall film 44 and the shielding portion 46 laminated above the lift-off film 40 are removed.

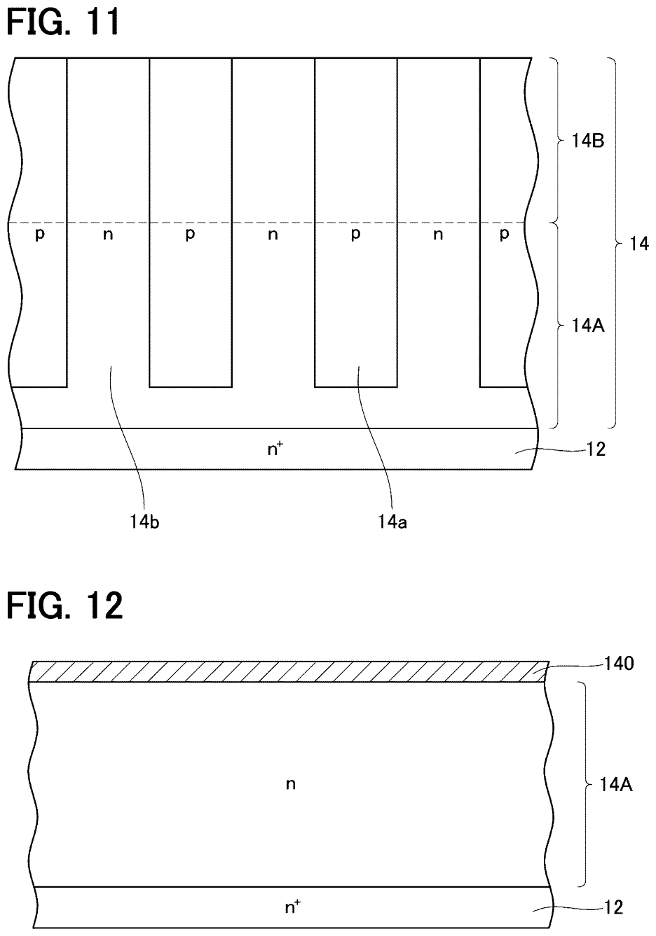

Next, as shown in FIG. 11, after an upper epitaxial layer 14B is grown above the lower epitaxial layer 14A using epitaxial growth techniques, a structure in which the p-type columns 14a and the n-type columns 14b are alternately and repeatedly arranged along one direction is formed within the upper epitaxial layer 14B. The upper epitaxial layer 14B is an example of a second conductivity type epitaxial layer. The upper epitaxial layer 14B having the above-described structure is formed by re-executing each of the processes described with reference to FIGS. 2 to 10. Specifically, a second ion implantation mask is patterned above the upper epitaxial layer 14B, the p-type columns 14a and n-type columns 14b are formed within the upper epitaxial layer 14B by implanting p-type impurities ions into the upper epitaxial layer 14B through openings of the second ion implantation mask, and the second ion implantation mask is lifted off. Accordingly, the p-type columns 14a and the n-type columns 14b formed within the upper epitaxial layer 14B and the p-type columns 14a and the n-type columns 14b formed within the lower epitaxial layer 14A are vertically connected, respectively, so as to form the superjunction structure.

Thereafter, the body region 16 containing the p-type impurity is formed above the upper epitaxial layer 14B using an epitaxial growth techniques, the source regions 18 and the body contact regions 19 are formed in predetermined regions within the body region 16 using ion implantation techniques, and various electrode structures (the trench gate 30, the drain electrode 22, and the source electrode 24) are formed. Accordingly, the semiconductor device 1 is completed.

The ion implantation mask used in the above-described manufacturing method uses the shielding portion 46 containing metal. The shielding portion 46 containing metal has a high shielding property against p-type impurity (aluminum in this example). Therefore, even if the thickness of the shielding portion 46 is thin, it can sufficiently shield the p-type impurity and prevent the p-type impurity from being implanted into the non-ion-implanted regions of the epitaxial layers 14A and 14B. Since the thickness of the shielding portion 46 is thin, the aspect ratio of the openings 54 formed in the shielding portion 46 becomes low. As a result, the occurrence of situations such as the shielding portion 46 between the openings 54 inclining can be suppressed.

The openings 54 of the ion implantation mask used in the above-described manufacturing method is formed by removing the mask forming walls 43 located between the shielding portion 46 embedded in advance in the mask forming layer 42. As a comparative example, consider a case where the openings 54 are formed by directly etching the shielding portion 46 containing tungsten. For example, when the shielding portion 46 is directly etched by using the RIE method, the etching proceeds along grain boundaries of the shielding portion 46. Since the grain size of tungsten is relatively large, the maximum surface roughness of the sidewalls of the openings 54 becomes large. On the other hand, in the above-described manufacturing method, since the shielding portion 46 is not directly etched, the maximum surface roughness of the openings 54 of the ion implantation mask is small. As a result, the maximum surface roughness at the interfaces between the p-type columns 14a and the n-type columns 14b formed in the epitaxial layers 14A and 14B is also reduced. The semiconductor device 1 manufactured by the above-described manufacturing method can suppress the imbalance of charge in the superjunction structure and can have high breakdown voltage characteristics.

The ion implantation mask used in the above-described manufacturing method has the sidewall film 44 that covers the side surfaces of the shielding portion 46. The material of the shielding portion 46 is tungsten, and the material of the sidewall film 44 is titanium nitride. The sidewall film 44 is made of a material having a smaller crystal grain size than that of the shielding portion 46. Since the sidewall film 44 covers the side surfaces of the shielding portion 46, sidewall film 44, which has a smaller crystal grain size, is exposed on the side surfaces of the openings 54 in the ion implantation mask. Therefore, the maximum surface roughness of the side surfaces of the openings 54 in the ion implantation mask is kept low. As a result, the maximum surface roughness at the interface between the p-type columns 14a and the n-type columns 14b formed in the epitaxial layers 14A and 14B is also reduced. The semiconductor device 1 manufactured by the above-described manufacturing method can suppress the imbalance of charge in the superjunction structure and can have high breakdown voltage characteristics.

The crystal grain size of tungsten, which is the material of the shielding portion 46, is 17 nm to 30 nm depending on the surface orientation. For example, when the shielding portion 46 is directly etched using the RIE method to form the openings of the ion implantation mask, various surface orientations are exposed on the side surfaces of the openings 54 of the ion implantation mask. Thus, the maximum surface roughness of the openings 54 becomes 30 nm. It is considered that the maximum surface roughness at the interfaces between the p-type columns 14a and the n-type columns 14b formed using such an ion implantation mask will also be 30 nm. For example, in the case of a narrow pitch where the pitch of the p-type columns 14a and the n-type columns 14b in the repetition direction is 0.4 μm or less, if the maximum surface roughness at the interfaces between the p-type column 14a and the n-type columns 14b is as large as 30 nm, there is concern that imbalance of charge may occur in the superjunction structure. On the other hand, with the ion implantation mask of the above-described manufacturing method, since the shielding portion 46 is not directly etched, the maximum surface roughness of the openings 54 of the ion implantation mask is less than 30 nm. Thus, the maximum surface roughness at the interfaces between the p-type columns 14a and the n-type columns 14b is less than 30 nm. Furthermore, since the sidewall film 44 with a small crystal grain size is exposed on the side surfaces of the openings 54 of the ion implantation mask, the maximum surface roughness of the openings 54 can be further reduced to less than 25 nm, less than 20 nm, less than 15 nm, or even less than 10 nm. The maximum surface roughness at the interfaces between the p-type columns 14a and the n-type columns 14b is not particularly limited, and is, for example, 0.42 nm or more. As described above, the above-described manufacturing method can suppress imbalance of charge in the superjunction structure and achieve high breakdown voltage characteristics even when the pitch of the p-type columns 14a and the n-type columns 14b in the repetition direction is 0.4 μm or less.

In the above-described manufacturing method, when forming the grooves 52 in the mask forming layer 42 and further, when removing the mask forming walls 43, the lift-off film 40 is left above the epitaxial layers 14A and 14B. According to this method, the lift-off film 40 can function as a protective film. Therefore, damage to the upper surfaces of the epitaxial layers 14A and 14B can be suppressed. In addition, the lift-off film 40 left above the epitaxial layers 14A and 14B can function as a through film during ion implantation of the p-type impurity. Therefore, damage to the upper surfaces of the epitaxial layers 14A and 14B during ion implantation can also be suppressed.

In the ion implantation mask used in the above-described manufacturing method, the lift-off film 40 is left above the epitaxial layers 14A and 14B. The presence of the lift-off film 40 suppresses metal contamination of the epitaxial layers 14A and 14B by the metal (tungsten in this example) contained in the shielding portion 46. For example, if the metal contained in the shielding portion 46 remains between the lower epitaxial layer 14A and the upper epitaxial layer 14B, there is a concern that the charge balance of the superjunction structure will be disrupted, resulting in a decrease in the breakdown voltage of the semiconductor device 1. Therefore, the above-described manufacturing method is particularly useful when forming a superjunction structure in two steps.

### (Second Manufacturing Method)

Hereinafter, a second manufacturing method of the semiconductor device 1 will be described with reference to FIGS. 12 to 20. The processes up to the process shown in FIG. 2 are the same as those in the first manufacturing method.

Next, as shown in FIG. 12, for example, using deposition techniques such as sputtering, a lift-off film 140 is formed above the lower epitaxial layer 14A. The lift-off film 140 is not particularly limited, and may be, for example, an oxide film such as silicon oxide. A thickness of the lift-off film 140 is not particularly limited, and may be, for example, 20 nm.

Next, as shown in FIG. 13, for example, using deposition techniques such as sputtering, a diffusion barrier film 141 is formed above the lift-off film 140. The diffusion barrier film 141 is not particularly limited, and may be, for example, a silicon nitride (SiN) film. A thickness of the diffusion barrier film 141 is not particularly limited, and may be, for example, 20 nm.

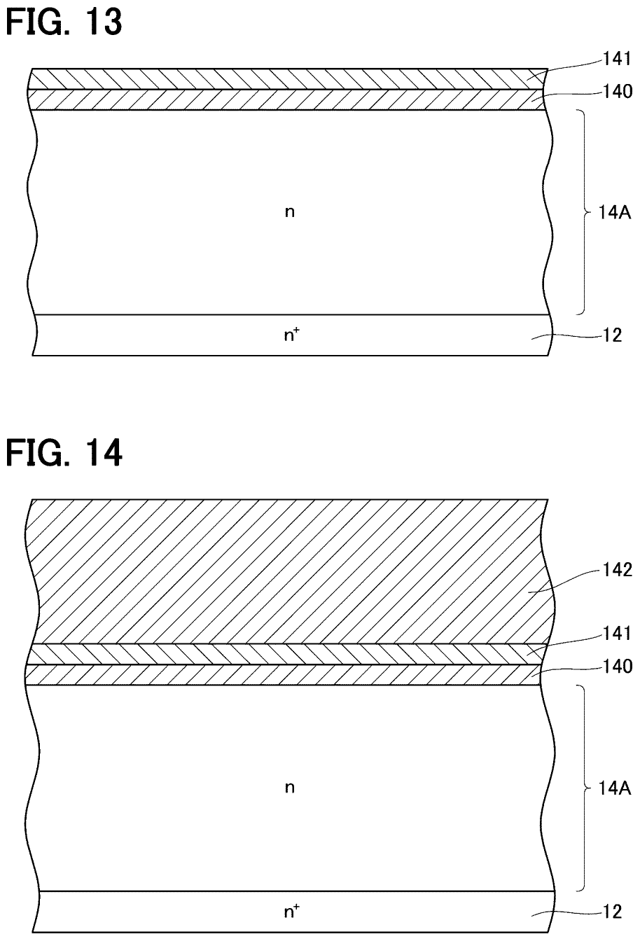

Next, as shown in FIG. 14, for example, a mask forming layer 142 is formed above the diffusion barrier film 141 using deposition techniques such as CVD, for example. The mask forming layer 142 is not particularly limited, and may be, for example, an oxide film such as silicon oxide. A thickness of the mask forming layer 142 is not particularly limited, and may be, for example, 1.1 μm.

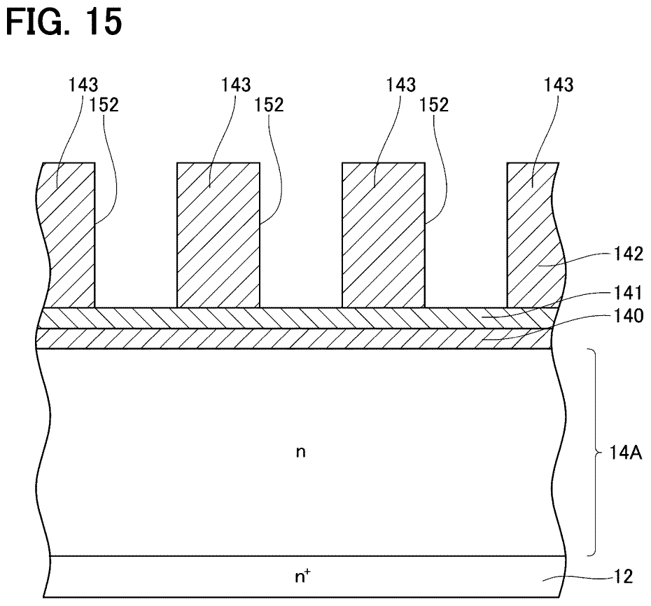

Next, as shown in FIG. 15, a plurality of grooves 152 are formed in the mask forming layer 142 by using etching techniques such as RIE or wet etching. Portions of the mask forming layer 142 that remain between the grooves 152 are referred to as mask forming walls 143. The grooves 152 extend from an upper surface of the mask forming layer 142 toward the diffusion barrier film 141. In this example, the grooves 152 penetrate through the mask forming layer 142 and reach the diffusion barrier film 141. In another example, there may be case where the grooves 152 do not penetrate through the mask forming layer 142 and portions of the mask forming layer 142 remain on the diffusion barrier film 141.

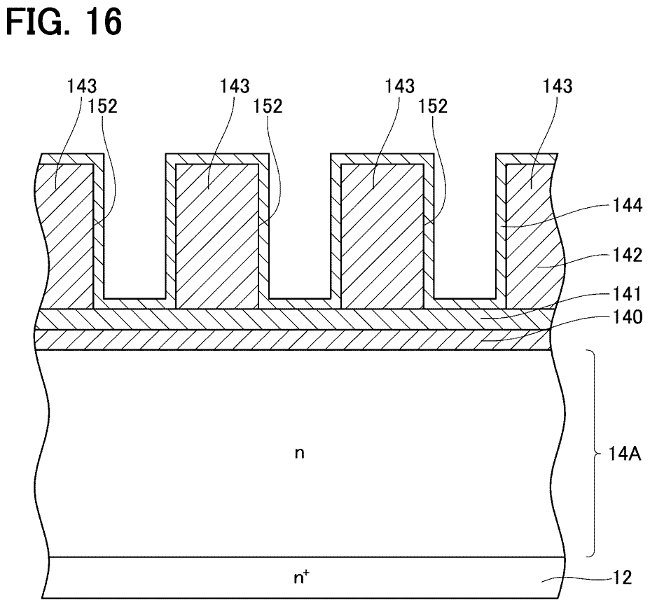

Next, as shown in FIG. 16, a sidewall film 144 is formed on the inner walls of the grooves 152 using deposition techniques such as atomic layer deposition, for example. The sidewall film 144 is also formed on upper surfaces of the mask forming walls 143. The sidewall film 144 is not particularly limited, and may be, for example, a metal nitride film. In this example, the sidewall film 144 is made of titanium nitride (TIN). In atomic layer deposition for forming the titanium nitride film, the materials used are not particularly limited, but titanium tetrachloride (TiCl₄), which is a metal precursor gas, and ammonia (NH₃), which is a nitrogen precursor gas, may be used.

In the second manufacturing method, the sidewall film 144 is formed using atomic layer deposition. Compared to the first manufacturing method in which the sidewall film 44 is formed by sputtering, the sidewall film 144 formed using atomic layer deposition can be deposited favorably on the inner walls of the grooves 152 even when the width of the grooves 152 is narrow. Therefore, the pitch of the grooves 152 can be made narrower, and consequently, the pitch of the superjunction structure can also be reduced. On the other hand, in atomic layer deposition, a metal chloride is used as the metal precursor gas. Therefore, there is a concern that chlorine contained in the metal chloride may diffuse into the lower epitaxial layer 14A. Chlorine that has diffused into the lower epitaxial layer 14A can cause fluctuations in the gate threshold voltage during cyclic operation. In the second manufacturing method, the diffusion barrier film 141 is provided between the grooves 152 and the lower epitaxial layer 14A. The diffusion barrier film 141 is made of a material that has lower chlorine diffusivity than the lift-off film 140. Since the diffusion barrier film 141 is provided, even when the sidewall film 144 is formed using atomic layer deposition, the diffusion of chlorine contained in the metal chloride into the lower epitaxial layer 14A can be suppressed.

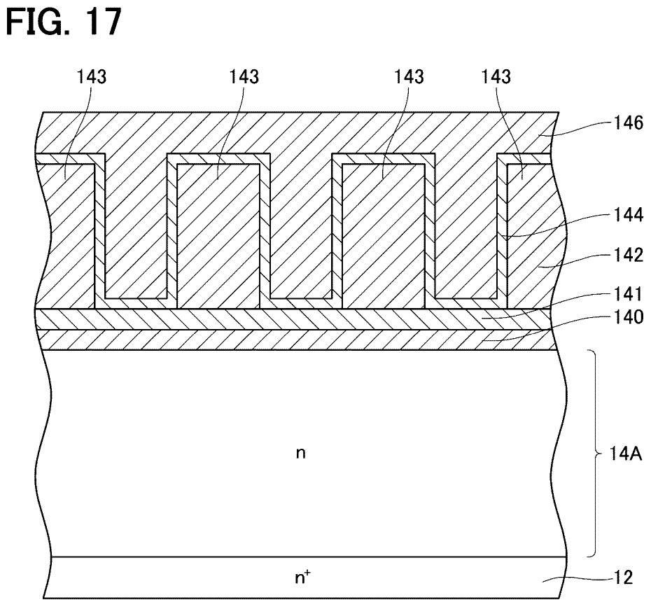

Next, as shown in FIG. 17, a shielding portion 146 is embedded in the grooves 152 using vapor deposition techniques such as atomic layer deposition. The shielding portion 146 is also formed above the upper surfaces of the mask forming walls 143, and completely fills the inside of the grooves 152. The shielding portion 146 is a film containing metal. The shielding portion 146 is not particularly limited, and may be, for example, a single metal film. In this example, the shielding portion 146 is made of tungsten (W). In atomic layer deposition, although not particularly limited, tungsten hexafluoride (WF₆), which is a metal precursor gas, and hydrogen (H₂), which is a reducing gas, may be used. The material of the shielding portion 146 may also be tungsten silicide (WSi₂).

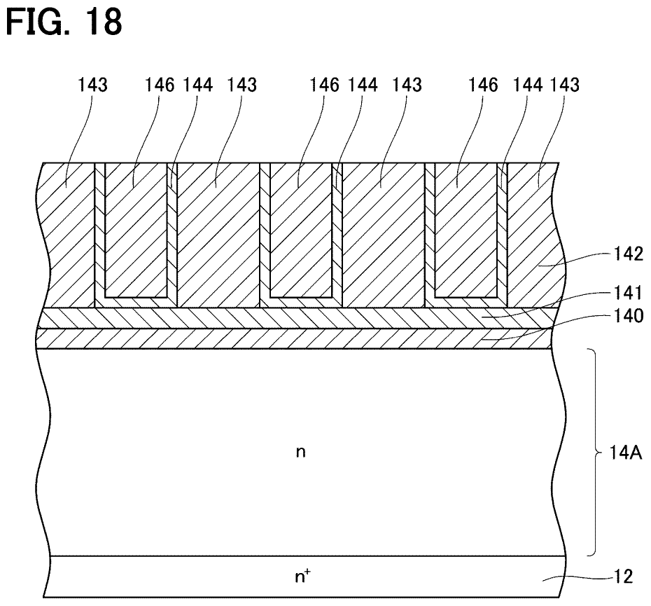

Next, as shown in FIG. 18, the shielding portion 146 that has been formed above the upper surfaces of the mask forming walls 143 is removed using planarization techniques such as CMP, for example. In this planarization process, the sidewall films 144 that has been formed above the upper surfaces of the mask forming walls 143 is also removed, and the mask forming walls 143 are exposed.

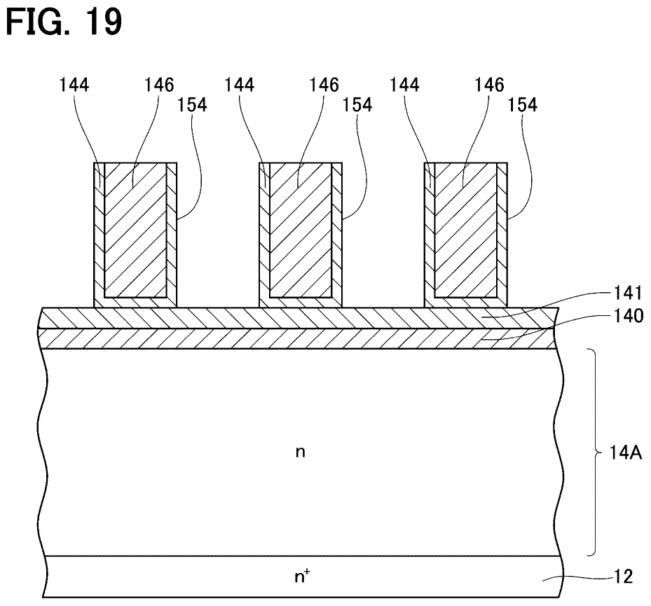

Next, as shown in FIG. 19, using etching techniques such as RIE or wet etching, the mask forming walls 143 present between the shielding portion 146 is removed to form openings 154, thereby forming an ion implantation mask. This ion implantation mask is another example of the first ion implantation mask. The diffusion barrier film 141 is exposed at bottom surfaces of the openings 154. In another example, the mask forming walls 143 may partially remain.

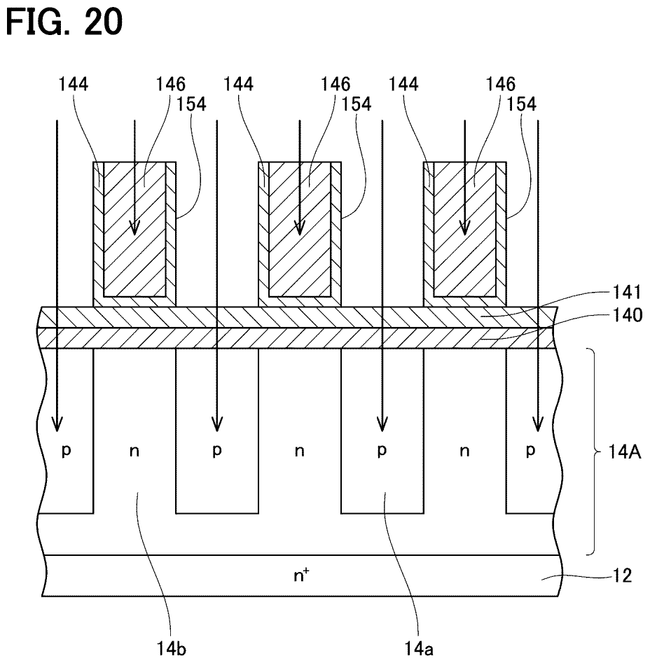

Next, as shown in FIG. 20, using ion implantation techniques, p-type impurity is ion-implanted into the lower epitaxial layer 14A through the openings 154 of the ion implantation mask. The p-type impurity is not particularly limited, but may be, for example, aluminum. Regions of the lower epitaxial layer 14A into which the p-type impurity has been introduced become the p-type columns 14a, and regions sandwiched between the p-type columns 14a become the n-type columns 14b. As a result, a structure in which the p-type columns 14a and the n-type columns 14b are alternately and repeatedly arranged along one direction is formed within the lower epitaxial layer 14A.

Next, as in the first manufacturing method, the lift-off film 140, the diffusion barrier film 141, the sidewall film 144, and the shielding portion 146 that have been deposited above the lower epitaxial layer 14A are removed using a lift-off method. Accordingly, the lower epitaxial layer 14A in the state shown in FIG. 10 is formed. Furthermore, after an upper epitaxial layer 14B is grown by crystal growth on the lower epitaxial layer 14A using epitaxial growth techniques, a structure in which p-type columns 14a and n-type columns 14b are alternately and repeatedly arranged along one direction is formed within the upper epitaxial layer 14B. The upper epitaxial layer 14B having the above-described structure is formed by re-executing each of the processes described in FIGS. 12 to 20. Accordingly, the p-type columns 14a and the n-type columns 14b formed within the upper epitaxial layer 14B and the p-type columns 14a and the n-type columns 14b formed within the lower epitaxial layer 14A are vertically connected, respectively, so as to form the superjunction structure. Thereafter, the semiconductor device 1 is completed through processes similar to those of the first manufacturing method.

As described above, the second manufacturing method can suppress chlorine diffusion when the sidewall film 144 is formed using atomic layer deposition by providing the diffusion barrier film 141, and can suppress fluctuations in the gate threshold voltage during cyclic operation. In addition, since the second manufacturing method forms the sidewall film 144 using atomic layer deposition, the pitch of the grooves 152 in the mask forming layer 142 can be reduced due to good coverage, and consequently, the pitch of the superjunction structure can also be reduced. As described above, the second manufacturing method is a useful technique for miniaturizing the superjunction structure.

Although specific examples of the present disclosure have been described in detail above, these are merely examples and do not limit the scope of claims. The techniques described in the claims include various modifications and modifications of the specific examples illustrated above. In addition, the technical elements described in the present specification or the drawings exhibit technical usefulness alone or in various combinations, and are not limited to the combinations described in the claims at the time of filing. In addition, the techniques illustrated in the present specification or the drawings can achieve multiple purposes at the same time, and achieving one of the purposes itself has technical usefulness.

What is claimed is:

1. A manufacturing method of a semiconductor device having a superjunction structure in which first conductivity type columns and second conductivity type columns are alternately and repeatedly arranged along at least one direction, the manufacturing method comprising:
patterning an ion implantation mask above a second conductivity type semiconductor layer; and
after the patterning the ion implantation mask, forming the first conductivity type columns and the second conductivity type columns within the second conductivity type semiconductor layer by implanting first conductivity type impurity ions into the second conductivity type semiconductor layer through openings in the ion implantation mask, wherein
the patterning the ion implantation mask includes:
forming a mask forming layer above the second conductivity type semiconductor layer;
forming grooves extending from an upper surface of the mask forming layer toward the second conductivity type semiconductor layer;
embedding a shielding portion containing metal into the grooves; and
removing the mask forming layer located between the shielding portion to form the openings.

2. The manufacturing method according to claim 1, wherein
the patterning the ion implantation mask further includes, between the forming the grooves and the embedding the shielding portion, forming a sidewall film on inner walls of the grooves, and
the sidewall film has a smaller crystal grain size than the shielding portion.

3. The manufacturing method according to claim 2, wherein
the forming the sidewall film is performed using atomic layer deposition.

4. The manufacturing method according to claim 2, wherein
the sidewall film is made of titanium nitride.

5. The manufacturing method according to claim 1, wherein
the forming the grooves and the forming the openings include partially leaving the mask forming layer above the second conductivity type semiconductor layer to form a lift-off film.

6. The manufacturing method according to claim 3, wherein
in the patterning of the ion implantation mask, the forming the mask forming layer includes sequentially forming a lift-off film, a diffusion barrier film, and the mask forming layer above the second conductivity type semiconductor layer in order, and
the diffusion barrier film is made of a material that has lower diffusivity for chlorine than the lift-off film.

7. The manufacturing method according to claim 6, wherein
the diffusion barrier film is made of silicon nitride.

8. The manufacturing method according to claim 5, further comprising
after the forming the first conductivity type columns and the second conductivity type columns, lifting off the ion implantation mask by etching the lift-off film.

9. The manufacturing method according to claim 8, wherein the ion implantation mask is a first ion implantation mask, and the manufacturing method further comprising:
after the lifting off the first ion implantation mask, forming a second conductivity type epitaxial layer above the second conductivity type semiconductor layer;
patterning a second ion implantation mask above the second conductivity type epitaxial layer;
forming the first conductivity type columns and the second conductivity type columns within the second conductivity type epitaxial layer by implanting first conductivity type impurity ions into the second conductivity type epitaxial layer through openings in the second ion implantation mask; and
lifting off the second ion implantation mask, wherein
the first conductivity type columns and the second conductivity type columns formed within the second conductivity type epitaxial layer are connected to the first conductivity type columns and the second conductivity type columns formed within the second conductivity type semiconductor layer, respectively, to form the superjunction structure.

10. The manufacturing method according to claim 1, wherein
the metal contained in the shielding portion includes at least tungsten.

11. A semiconductor device comprising:
a superjunction structure is which first conductivity type columns and second conductivity type columns are alternately and repeatedly arranged in at least one direction as a repetition direction, wherein
each of the first conductivity type columns and the second conductivity type columns is made of silicon carbide,
a pitch of the first conductivity type columns and the second conductivity type columns in the repetition direction is 0.4 μm or less, and
a maximum surface roughness at interfaces between the first conductivity type columns and the second conductivity type columns is less than 30 nm.

12. The semiconductor device according to claim 11, wherein
each of the first conductivity type columns and the second conductivity type columns has an aspect ratio of 8.5 or more.
